(19) United States
(12) Patent Application Publication
(10) Pub. No.: US 2026/0150195 A1
(43) Pub. Date: May 28, 2026

(54) BOTTOM-UP THROUGH GLASS VIA PLATING FOR GLASS CORE

(71) Applicant: Intel Corporation, Santa Clara, CA (US)

(72) Inventor: Yonggang LI, Chandler, AZ (US)

(21) Appl. No.: 18/961,010

(22) Filed: Nov. 26, 2024

(51) Int. Cl. H05K 1/11; H05K 1/03; H05K 1/18; H05K 3/00

(52) U.S. Cl. CPC H05K 1/115; H05K 1/0306; H05K 1/181; H05K 3/0029; H05K 2201/09545; H05K 2201/09554; H05K 2201/09563; H05K 2201/09618; H05K 2201/09827; H05K 2201/10212; H05K 2201/10522; H05K 2201/10734

(57) ABSTRACT

Embodiments disclosed herein include an apparatus that includes a substrate that comprises a glass layer. In an embodiment, an opening is provided through a thickness of the substrate, and a via is in the opening. In an embodiment, the via directly contacts a sidewall of the opening at a first location, and a gap is provided between the via and the sidewall of the opening at a second location. In an embodiment, the via is electrically conductive.

### BACKGROUND

Glass cores for package substrates are an attractive option due to the increased stiffness, planarity, and routing density that they provide compared to existing organic cores. However, the brittle nature of glass provides several challenges with respect to manufacturing. One issue that is present for glass cores is the high stress that is generated by vias that are formed through the glass core (i.e., through glass vias (TGVs)). With traditional plating, a seed layer is provided along the sidewalls of the via opening, and the via is plated out from the sidewalls. This provides a strong mechanical coupling between the vias and the glass core. During thermal cycling, the via expands more than the glass core, and this generates a high stress in the glass core. The high stress may result in cracking or other defects that significantly impact the reliability of the glass core.

### BRIEF DESCRIPTION OF THE DRAWINGS

FIGS. 1A-1D are cross-sectional illustrations that depict a process for plating a via with a bottom-up process, in accordance with an embodiment.

FIGS. 2A-2G are cross-sectional illustrations that depict a process for forming a package substrate with a glass core that includes vias that are plated with a bottom-up process, in accordance with an embodiment.

FIG. 3 is a flow diagram of a process for plating vias in a glass core with a bottom-up process, in accordance with an embodiment.

FIG. 4 is a cross-sectional illustration of an electronic system that comprises a package substrate with a glass core that includes vias that are plated with a bottom-up process, in accordance with an embodiment.

FIG. 5 is a schematic of a computing device built in accordance with an embodiment.

### EMBODIMENTS OF THE PRESENT DISCLOSURE

Described herein are glass substrates with through glass vias (TGVs) that are plated with a bottom-up process, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, existing glass cores provide improved stiffness, planarity, and routing density compared to organic cores. However, the strong mechanical coupling between the through glass vias (TGVs) and the glass core results in significant stress being induced in the glass core during thermal cycling. As such, cracking or other damage to the glass core may occur. This negatively impacts the reliability of such glass cores. Further, the high aspect ratios of the TGVs make it difficult to form void-free TGVs in a cost-effective manner. For example, an atomic layer deposition process may be used for seeding the TGV side walls. This may be followed with an electrolytic plating solution that includes delicate engineering around plating dynamics at different locations of the TGV geometry and different stages of the plating. However, atomic layer deposition is a slow and expensive process, and such a process may not be affordable with high volume manufacturing environments. The sidewall driven electrolytic plating becomes very challenging as TGV aspect ratio (height:width) reaches 10:1 or more, and the process quality is sensitive to the sidewall profile of the TGVs.

Accordingly, embodiments disclosed herein include a bottom-up plating process in order to form the TGVs. In a bottom-up plating process, an electrically conductive layer is provided across a bottom of the via opening. The plating proceeds in a vertical direction up through the via opening. In such an embodiment, the interface between the TGV and the sidewall has a weaker mechanical coupling than traditional plating from a seed layer along the sidewall of the via opening. For example, the TGV may have a sidewall that contacts the sidewall of the via opening in some locations and is spaced away from sidewall of the via opening by a gap (e.g., an air gap) at other locations. The gaps may have a width between the sidewall of the via opening and the TGV that is in the submicron scale. Even at locations where the TGV metal is in contact with the glass, the coupling is weak, and a gap can be developed after the formation of the TGV metal due to the thermo-mechanical stress incurred in the manufacturing processes or in use conditions. As such, the electrical conductivity is not impacted while also allowing for improved mechanical reliability of the glass core. In addition, the bottom-up plating process is insensitive to TGV sidewall profile and provides quality TGV metallization with improved process robustness.

In some embodiments, the conductive layer below the via opening may be supported by a carrier. In some embodiments, the carrier may be coupled to the glass core by the conductive layer. For example, the conductive layer may be a conductive adhesive. In some instances, the conductive adhesive may also comprise an underlying conductive seed layer (e.g., comprising titanium and/or copper) to improve the electrical conductivity of the conductive adhesive in order to improve the plating process.

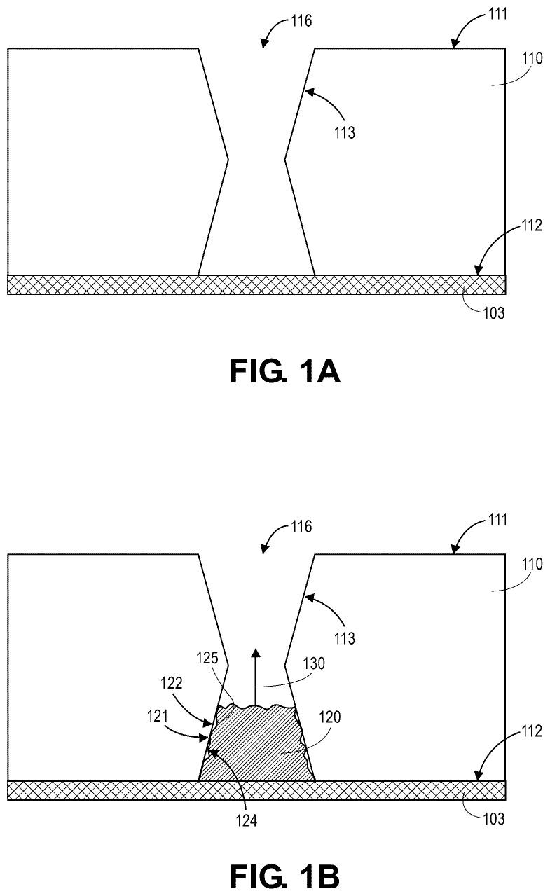

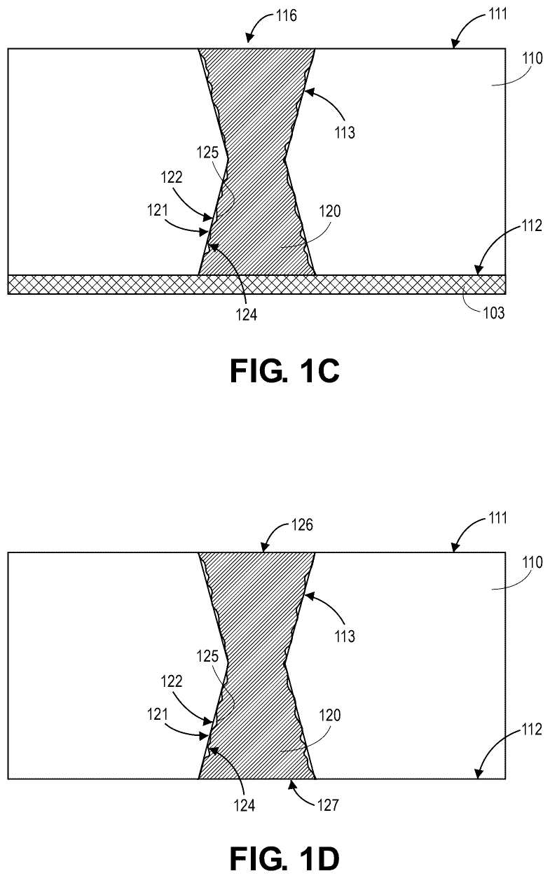

Referring now to FIGS. 1A-1D , a series of cross-sectional illustrations depicting a process for forming a TGV in a glass core with a bottom-up plating process is shown, in accordance with an embodiment.

Referring now to FIG. 1A, a cross-sectional illustration of a glass core 110 is shown, in accordance with an embodiment. In an embodiment, a via opening 116 is provided through a thickness of the glass core 110. The via opening 116 may be formed with any suitable process. For example, a laser assisted etching process may be used to form the via opening 116 in some embodiments. In an embodiment, the via opening 116 may be a high aspect ratio via opening 116. For example, an aspect ratio (height:diameter) of the via opening 116 may be 5:1 or greater, 10:1 or greater, or 20:1 or greater. Though, embodiments may also be used with smaller aspect ratio via openings 116 as well.

In the illustrated embodiment, sidewalls 113 of the via opening 116 have a slope relative to a top surface 111 and a bottom surface 112 of the glass core 110. The via opening 116 may have sidewalls 113 that form an hourglass shape. Though, in other embodiments, the sidewalls 113 may have a single slope to form a via opening 116 with a single taper. In other embodiments, the sidewalls 113 may be substantially vertical (i.e., orthogonal to the top surface 111), the sidewalls 113 may be curved (e.g., non-planar), or have any other suitable profile.

In an embodiment, a conductive layer 103 may be provided on the bottom surface 112 of the glass core 110. The conductive layer 103 may comprise a metallic material (e.g., titanium and/or copper). As will be described in greater detail herein, the conductive layer 103 may also be a conductive adhesive layer in order to couple the glass core 110 to a carrier substrate (not shown in FIG. 1A). The conductive layer 103 may span across the via opening 116. As such, a portion of the conductive layer 103 is exposed by the via opening 116 in order to allow for the bottom-up plating process described in greater detail herein.

In an embodiment, the glass core 110 may be substantially all glass. The glass core 110 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 110 may be distinguished from, for example, the “prepreg” or “FR4” core of a Printed Circuit Board (PCB) substrate which typically comprises glass fibers embedded in a resinous organic material, such as an epoxy.

The glass core 110 may have any suitable dimensions. In a particular embodiment, the glass core 110 may have a thickness that is approximately 50 μm or greater. For example, the thickness of the glass core 110 may be between approximately 50 μm and approximately 1.4 mm. Though, smaller or larger thicknesses may also be used. The glass core 110 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 110 (from an overhead plan view) may be between approximately 10 mm×10 mm and approximately 250 mm×250 mm. In an embodiment, the glass core 110 may have a first side that is perpendicular or orthogonal to a second side. In a more general embodiment, the glass core 110 may comprise a rectangular prism volume with sections (e.g., vias) removed and filled with other materials (e.g., metal, etc.).

The glass core 110 may comprise a single monolithic layer of glass. In other embodiments, the glass core 110 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 110 may each have a thickness less than approximately 50 μm. For example, discrete layers of glass in the glass core 110 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 110 may be any suitable glass formulation that has the necessary mechanical robustness and compatibility with semiconductor packaging manufacturing and assembly processes. For example, the glass core 110 may comprise aluminosilicate glass, borosilicate glass, alumino-borosilicate glass, silica, fused silica, or the like. In some embodiments, the glass core 110 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 110 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 110 may comprise at least 23 percent silicon (by weight) and at least 26 percent oxygen (by weight). In some embodiments, the glass core 110 may further comprise at least 5 percent aluminum (by weight).

Referring now to FIG. 1B, a cross-sectional illustration of the glass core 110 after a portion of the TGV 120 is plated is shown, in accordance with an embodiment. As indicated by the arrow 130, the plating of the TGV 120 extends in a vertical direction from the conductive layer 103 in a bottom-up manner. The plating may be any suitable electroplating process. Due to the bottom-up plating process, the sidewalls 124 may have a textured surface that interfaces with the sidewall 113 of the via opening 116. For example, the sidewalls 124 may be non-linear with peaks and valleys. In an embodiment, the sidewall 124 of the TGV 120 may directly contact the sidewall 113 of the via opening 116 at a first location 121, and the sidewall 124 of the TGV 120 may be spaced away from the sidewall of the via opening 116 by a gap 125 at a second location 122.

In an embodiment, the TGV 120 directly contacting the sidewall 113 of the via opening 116 may refer to there being no intermediary layer between the TGV 120 and the sidewall 113. For example, in existing plating processes, a seed layer or the like may be provided between the sidewall 113 of the via opening 116 and the sidewall 124 of the TGV 120. In an embodiment, the gap 125 may have any suitable dimension. For example, a width of the gap 125 between the sidewall 113 of the via opening 116 and the sidewall 124 of the TGV 120 may be up to approximately 5 μm, up to approximately 1 μm, up to approximately 0.5 μm, or up to approximately 0.1 μm. As noted above, the presence of the gaps 125 allows for weaker mechanical coupling between the TGV 120 and the glass core 110. Accordingly, stress related to coefficient of thermal expansion (CTE) mismatch between the glass core 110 and the TGV 120 may be mitigated, and the mechanical robustness of the glass core 110 is improved. Though, in some embodiments, a buffer layer (e.g., a polymer layer or other low modulus material) may line the sidewall 113 of the via opening 116. In such an embodiment, the TGV 120 may directly contact the buffer layer in some locations and be spaced apart from the buffer layer in other locations.

Referring now to FIG. 1C, a cross-sectional illustration of the glass core 110 after the plating of the TGV 120 is completed is shown, in accordance with an embodiment. As shown, the TGV 120 substantially fills the via opening, with the exception of the presence of gaps 125 at some locations along the height of the TGV 120. In a particular embodiment, a cross-sectional area of the TGV 120 along a plane (e.g., the plane illustrated in FIG. 1C) may be smaller than a cross-sectional area of the via opening 116 along the same plane. In an embodiment, the difference between the cross-sectional areas of the via opening 116 and the TGV 120 may be occupied by the cross-sectional area of all of the gaps 125. In an embodiment, the cross-sectional area of the TGV 120 along the plane may be approximately 95% or more of the cross-sectional area of the via opening 116, approximately 99% or more of the cross-sectional area of the via opening 116, approximately 99.5% or more of the cross-sectional area of the via opening 116, or approximately 99.9% or more of the cross-sectional area of the via opening. Stated differently, the via opening 116 may be substantially filled with only the TGV 120, and any remaining area of the via opening 116 may be occupied by gaps 125 (e.g., air gaps) between the sidewall 113 of the via opening 116 and the sidewall 124 of the TGV 120.

In an embodiment, the TGV 120 may comprise a substantially uniform composition across a line from a first edge of the TGV 120 to a second edge of the TGV 120 that is parallel to the top surface 111 or the bottom surface 112 of the glass core 110. For example, the TGV 120 may have a substantially uniform composition comprising copper. This is different than many existing via architectures that include a seed layer along the sidewall 113 of the via opening 116. In such an embodiment, the via may have a different composition along the outer edge of the via due to the seed layer. For example, concentrations of titanium or other seed layer materials may be present at the edge of the via. However, embodiments disclosed herein may comprise a substantially uniform composition from edge-to-edge since a bottom-up plating process is used.

Referring now to FIG. 1D, a cross-sectional illustration of the glass core 110 after the conductive layer 103 is removed is shown, in accordance with an embodiment. In an embodiment, the conductive layer 103 may be removed with an etching process, a polishing process, or the like. Due to the presence of the conductive layer 103, the bottom surface 127 of the TGV 120 may be substantially flat (i.e., planar) and coplanar with the bottom surface 112 of the glass core 110. In some embodiments, the top surface 126 of the TGV 120 may be polished or planarized so that the top surface 126 is substantially flat (i.e., planar) and coplanar with the top surface 111 of the glass core 110.

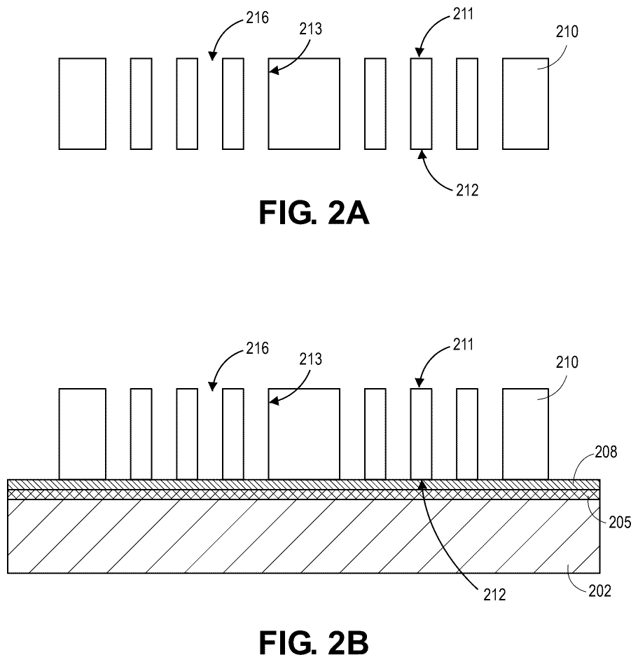

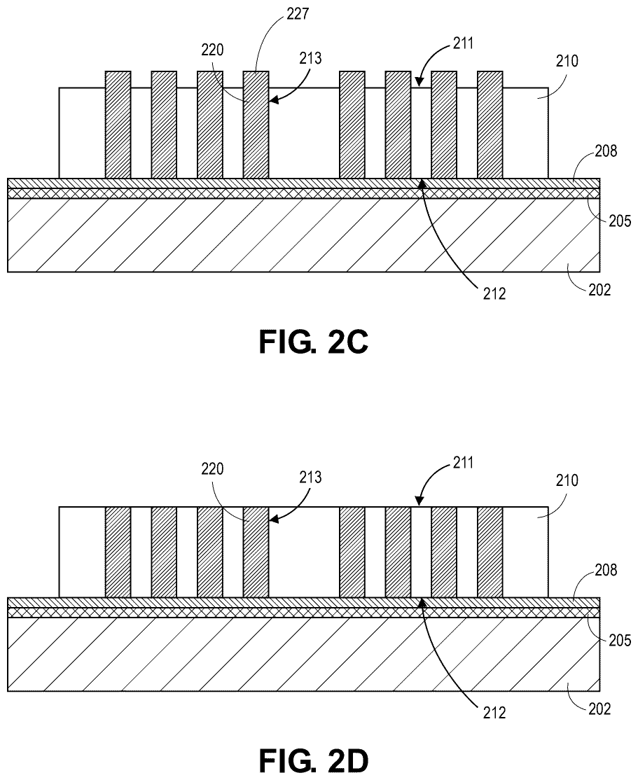

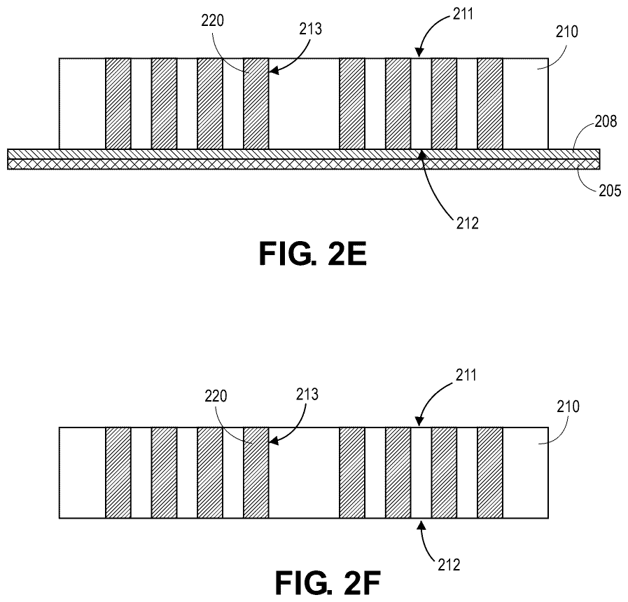

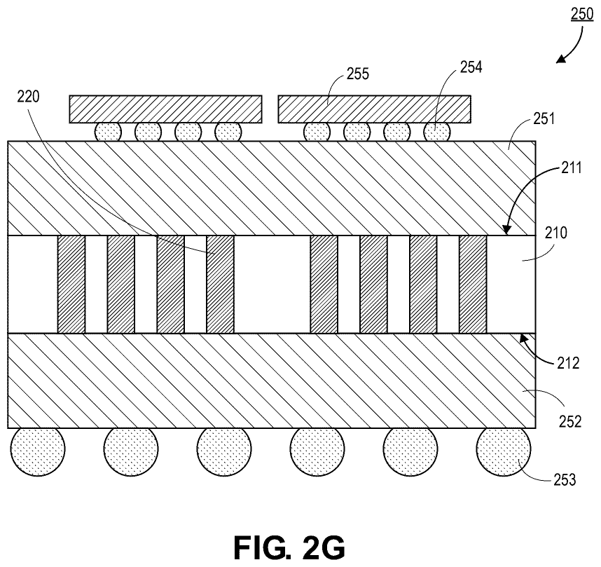

In the embodiments described above with respect to FIGS. 1A-1D , a bottom-up plating process is described in a manner that illustrates the resulting structure of the TGV 120. That is, the composition, structure, and/or interface with the sidewall 113 of the via opening 116 is described in detail. A more detailed example of how such a process may be implemented in a manufacturing setting is shown with respect to FIGS. 2A-2G. Particularly, the profile and detail of the TGVs in FIGS. 2A-2G is omitted in order to direct focus to the processing and structures used to enable the bottom-up plating process. Though, it is to be appreciated that the structure, composition, and/or the like of the TGVs in FIGS. 2A-2G may be similar to any of those described in greater detail herein.

Referring now to FIG. 2A, a cross-sectional illustration of a glass core 210 is shown, in accordance with an embodiment. In an embodiment, the glass core 210 may be similar to any of the glass cores or glass substrates describe in greater detail herein. In the illustrated embodiment, a single glass core 210 unit is shown. Though, it is to be appreciated that a glass panel or glass substrate with a plurality of glass core 210 units may be used in accordance with similar embodiments. In an embodiment, the glass core 210 may comprise a top surface 211 and a bottom surface 212. A plurality of via openings 216 may be formed through a thickness of the glass core 210. In the illustrated embodiment, the sidewalls 213 of the via openings 216 are substantially vertical. Though, it is to be appreciated that the sidewalls 213 may be sloped with respect to the top surface 211 or the bottom surface 212 in some embodiments. The via openings 216 may be formed with any suitable patterning process, such as a laser assisted etching process.

Referring now to FIG. 2B, a cross-sectional illustration of the glass core 210 after a carrier 202 is attached to the glass core 210 is shown, in accordance with an embodiment. In an embodiment, the glass core 210 may be coupled to the carrier 202 by an electrically conductive adhesive layer 208. In an embodiment, the electrically conductive adhesive layer 208 may comprise an electrically conductive adhesive (ECA), an anisotropic conductive film (ACF), or the like. In some embodiments, the electrical conductivity of the electrically conductive adhesive layer 208 may be enhanced by providing a conductive layer 205 between the electrically conductive adhesive layer 208 and the carrier 202. For example, the conductive layer 205 may comprise titanium and/or copper, or any other suitable electrically conductive material. Though, in some embodiments, the conductive layer 205 may be omitted when the electrically conductive adhesive layer 208 provides sufficient conductivity to drive the plating process. In an embodiment, the carrier 202 may comprise any suitable rigid material. In a particular embodiment, the carrier 202 may also comprise a glass layer.

Referring now to FIG. 2C, a cross-sectional illustration of the glass core 210 after a bottom-up plating process is used to form TGVs 220 in the via openings 216 is shown, in accordance with an embodiment. Since the only exposed conductive surfaces within the via openings 216 are the conductive adhesive layer 208 exposed at the bottom of the via openings 216, the TGVs 220 will plate up in a vertical direction. The bottom-up plating process may comprise an electroplating process or the like. In an embodiment, the TGVs 220 may have overburden 227 that extends above the top surface 211 of the glass core 210.

Similar to other embodiments described herein, the TGVs 220 may have a textured outer surface that provides direct contact with the sidewalls 213 of the via openings 216 at some locations and gaps between the TGVs 220 and the sidewalls of the via openings 216 at other locations. Additionally, it is to be appreciated that the TGVs 220 may directly contact the sidewalls 213 at some locations since there is no seed layer along the sidewalls 213 of the via openings 216. Further, the composition of the TGVs 220 may be substantially uniform since there is no seed layer within the via openings 216.

The profile of the sidewalls of the TGVs 220 may be similar to the profile of sidewalls 124 of the TGV 120 described in greater detail herein. For example, a cross-sectional area of the TGVs 220 along a plane may be smaller than a cross-sectional area of the via openings 216 along the same plane. Accordingly, less stress induced into the glass core 210 during thermal cycling, and the glass core 210 is more robust than previous solutions.

Referring now to FIG. 2D, a cross-sectional illustration of the glass core 210 after the overburden 227 of the TGVs is removed is shown, in accordance with an embodiment. In an embodiment, the overburden 227 may be removed with a polishing or planarizing process. For example, a chemical mechanical polishing (CMP) process may be used to remove the overburden 227.

Referring now to FIG. 2E, a cross-sectional illustration of the glass core 210 after the carrier 202 is removed is shown, in accordance with an embodiment. In an embodiment, the carrier 202 may be removed with any suitable process. For example, the carrier 202 may be removed by a thermal debonding process, a laser debonding process, a UV debonding process, or the like. Removal of the carrier 202 may expose a surface of the conductive layer 205.

Referring now to FIG. 2F, a cross-sectional illustration of the glass core 210 after the conductive layer 205 and the electrically conductive adhesive layer 208 are removed is shown, in accordance with an embodiment. In an embodiment, the conductive layer 205 may be removed with chemical etching process (e.g., a wet etching process) or a laser spallation process. In an embodiment, the electrically conductive adhesive layer 208 may be removed with a cleaning process or any other suitable process.

Referring now to FIG. 2G, a cross-sectional illustration of a package substrate 250 that comprises the glass core 210 is shown, in accordance with an embodiment. In an embodiment, the glass core 210 may be covered by a top buildup layer 251 over the top surface 211 and a bottom buildup layer 252 over the bottom surface 212 of the glass core 210. In an embodiment, the top buildup layer 251 and the bottom buildup layer 252 may each comprise a plurality of laminated organic layers (e.g., buildup film layers). In an embodiment, electrically conductive routing (not shown) within the top buildup layer 251 and the bottom buildup layer 252 may electrically couple the TGVs 220 to first level interconnects (FLIs) 254 and second level interconnects (SLIs) 253. The electrically conductive routing may include pads, traces, vias, and/or the like. In an embodiment, one or more dies 255 may be electrically coupled to the top buildup layer 251 by the FLIs 254. In some embodiments, a bridge substrate (not shown) that is embedded within the top buildup layer 251 or provided over the top buildup layer 251 may electrically couple two or more dies 255 together.

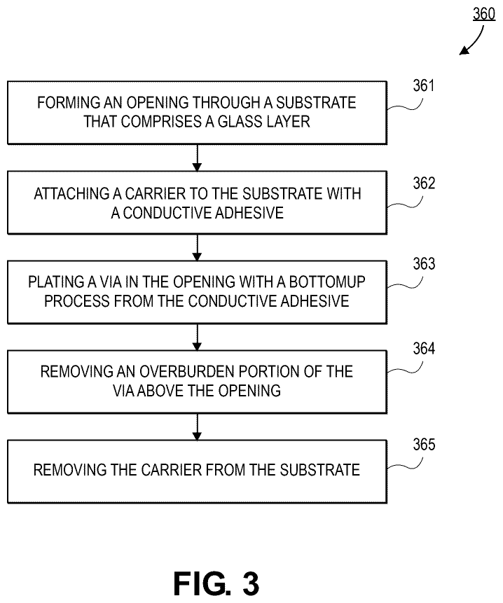

Referring now to FIG. 3, a flow diagram that depicts a process 360 for forming TGVs in a glass core with a bottom-up plating process is shown, in accordance with an embodiment. In an embodiment, the process 360 may be similar to the any of the bottom-up plating processes described in greater detail. For example, the TGVs may have a textured surface that reduces stress generation in the glass core due to CTE mismatch issues.

In an embodiment, the process 360 may begin with operation 361, which comprises forming an opening through a substrate that comprises a glass layer. In an embodiment, the substrate may be similar to any of the glass cores described in greater detail herein. In an embodiment, the opening may be considered a via opening. The opening may be formed with any suitable patterning process, such as a laser assisted etching process or the like.

In an embodiment, the process 360 may continue with operation 362, which comprises attaching a carrier to the substrate with a conductive adhesive. In an embodiment, the conductive adhesive may comprise an ECA or an ACF. In some embodiments, a conductive layer may be provided between the conductive adhesive and the carrier in order to improve the electrical conductivity of the conductive adhesive. For example, a layer comprising titanium and/or copper may be provided between the conductive adhesive and the carrier. The carrier may be a glass substrate or any other suitable rigid substrate material.

In an embodiment, the process 360 may continue with operation 363, which comprises plating a via in the opening with a bottom-up process from the conductive adhesive. For example, the conductive adhesive may span the opening, and the exposed portion of the conductive adhesive can be used as a seed layer to plate up the via. This allows for the via to be plated so that the opening is filled from bottom to top. Similar to other embodiments described herein, the plated via may have a textured surface that allows for the formation of submicron sized gaps between an edge of the via and the sidewall of the opening. Accordingly, the mechanical coupling is reduced, and stress induced by CTE mismatches between the via and the substrate are minimized. As such, reliability of the substrate is improved.

In an embodiment, the process may continue with operation 364, which comprises removing an overburden portion of the via above the opening. For example, a polishing process may be used to remove the overburden that is formed above a top surface of the substrate opposite from the carrier. For example, a CMP process may be used in some embodiments.

In an embodiment, the process 360 may continue with operation 365, which comprises removing the carrier from the substrate. In an embodiment, the carrier may be removed with any suitable debonding process, such as a laser debonding process, a thermal debonding process, a UV debonding process, or the like. After the carrier is removed, the conductive adhesive and any optional conductive layers may be removed as well. For example, an etching process, a polishing process, and/or a cleaning process may be used to remove the conductive adhesive and/or the conductive layer.

In an embodiment, the resulting substrate may then be integrated into a package substrate through typical buildup layer manufacturing processes. For example, a plurality of laminated layers are patterned to form electrical routing. The electrical routing in the buildup layers may electrically couple the via to a die coupled to the package substrate in some embodiments.

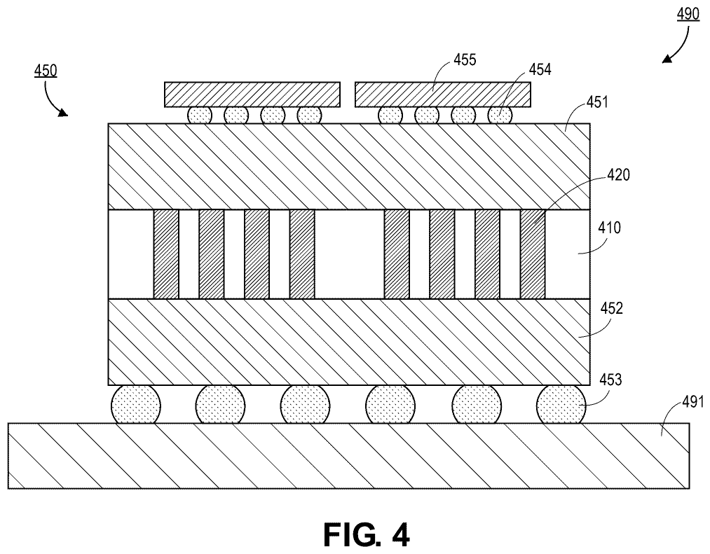

Referring now to FIG. 4, a cross-sectional illustration of an electronic system 490 is shown, in accordance with an embodiment. In an embodiment, the electronic system 490 may comprise a board 491, such as a printed circuit board (PCB), a motherboard, or the like. In an embodiment, the board 491 may be coupled to a package substrate 450 by SLIs 453. In an embodiment, the SLIs 453 may comprise solder balls, sockets, or the like.

In an embodiment, the package substrate 450 may be similar to any of the package substrates described in greater detail herein. In an embodiment, the package substrate 450 may comprise a glass core 410 with TGVs 420. The TGVs 420 may be formed with a bottom-up plating process such as any of those described in greater detail herein. In an embodiment, the TGVs 420 may have a textured surface that allows for a reduction in an amount of stress that is induced in the glass core 410 due to weaker mechanical coupling compared to existing plating processes. The TGVs 420 may be similar to any of the TGVs described in greater detail herein. In an embodiment, the package substrate 450 may also comprise buildup layers 451 and 452 that are provided over and under the glass core 410.

In an embodiment, one or more dies 455 may be coupled to the buildup layer 451 by FLIs 454. The FLIs 454 may be any suitable FLI architecture, such as solder balls, copper bumps, hybrid bonding interfaces, or the like. In an embodiment, the one or more dies 455 may be any type of die (e.g., a processor die (e.g., a central processing unit (CPU), a graphics processing unit (GPU), an XPU), a memory die, a communications die, a power management die, and/or the like). In an embodiment, two or more dies 455 may be electrically coupled together by a bridge (not shown) that is embedded in the buildup layer 451 or provided over the buildup layer 451.

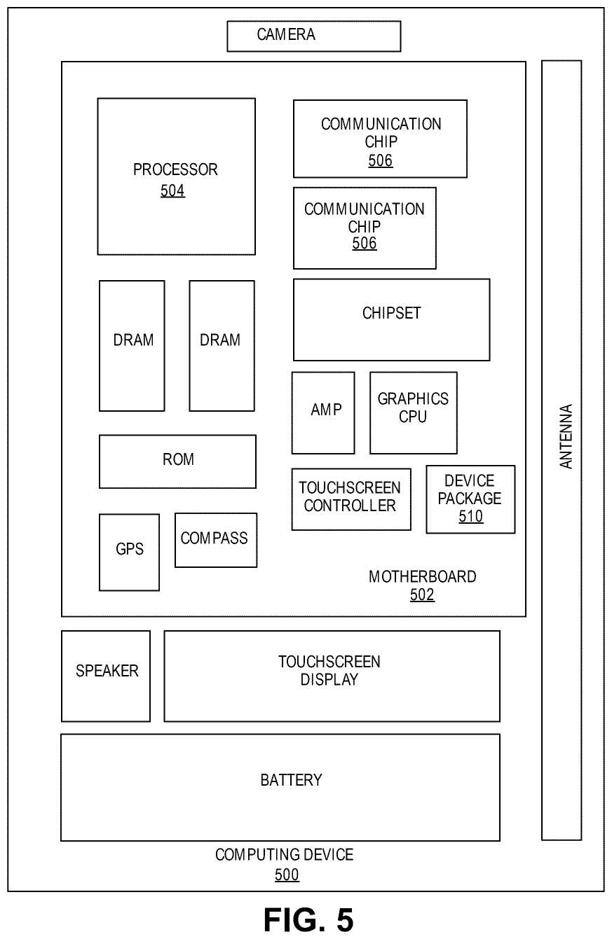

FIG. 5 illustrates a computing device 500 in accordance with one implementation of the disclosure. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504. In an embodiment, a device package 510 is coupled to the board 502. One or both of the processor 504 or the communication chip 506 may be coupled to the board 502 through the device package 510.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the disclosure, the integrated circuit die of the processor may be part of a package substrate with a glass core that comprises TGVs that are formed with a bottom-up plating process, in accordance with embodiments described herein. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the disclosure, the integrated circuit die of the communication chip may be part of a package substrate with a glass core that comprises TGVs that are formed with a bottom-up plating process, in accordance with embodiments described herein.

In an embodiment, the computing device 500 may be part of any apparatus. For example, the computing device may be part of a personal computer, a server, a mobile device, a tablet, an automobile, or the like. That is, the computing device 500 is not limited to being used for any particular type of system, and the computing device 500 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate, wherein the substrate comprises a glass layer; an opening through a thickness of the substrate; and a via in the opening, wherein the via directly contacts a sidewall of the opening at a first location, wherein a gap is provided between the via and the sidewall of the opening at a second location, and wherein the via is electrically conductive.

Example 2: the apparatus of Example 1, wherein the via comprises substantially planar top and bottom surfaces, and wherein a sidewall of the via is non-linear.

Example 3: the apparatus of Example 1 or Example 2, wherein the sidewall of the opening has a slope with respect to a top surface of the substrate.

Example 4: the apparatus of Examples 1-3, wherein a composition of the via is substantially uniform across a line from a first edge of the via to a second edge of the via, and wherein the line is parallel to a top surface and/or a bottom surface of the substrate.

Example 5: the apparatus of Example 4, wherein the composition comprises substantially copper.

Example 6: the apparatus of Examples 1-5, wherein an aspect ratio (height:width) of the opening is approximately 10:1 or greater.

Example 7: the apparatus of Examples 1-6, wherein the gap has a width that is up to one micron.

Example 8: the apparatus of Examples 1-7, wherein the via has a first cross-sectional area along a plane and the opening has a second cross-sectional area along the plane, and wherein the first cross-sectional area is smaller than the second cross-sectional area.

Example 9: the apparatus of Example 8, wherein a difference between the first cross-sectional area and the second cross-sectional area is a third cross-sectional area along the plane, and wherein the third cross-sectional area along the plane is a voided area that comprises the gap.

Example 10: the apparatus of Examples 1-9, wherein the substrate is a core of a package substrate.

Example 11: an apparatus, comprising: a substrate, wherein the substrate comprises a glass layer; an opening through a thickness of the substrate; and a via in the opening, wherein the via has a first cross-sectional area along a plane and the opening has a second cross-sectional area along the plane, and wherein the first cross-sectional area is smaller than the second cross-sectional area.

Example 12: the apparatus of Example 11, wherein a sidewall of the via is non-linear.

Example 13: the apparatus of Example 11 or Example 12, wherein the opening has an hourglass shaped profile.

Example 14: the apparatus of Examples 11-13, wherein the via comprises a composition that is substantially copper.

Example 15: the apparatus of Examples 11-14, wherein the substrate is a core of a package substrate.

Example 16: the apparatus of Example 15, further comprising: a die coupled to the package substrate; and a board coupled to the package substrate.

Example 17: a method, comprising: attaching a carrier to a substrate with a conductive adhesive, wherein the conductive adhesive spans across an opening through the substrate; plating a via in the opening with a bottom-up process from the conductive adhesive; and removing the carrier from the substrate.

Example 18: the method of Example 17, wherein the via directly contacts a sidewall of the opening at a first location along the sidewall of the opening, and wherein the via is spaced away from the sidewall of the opening by a gap at a second location along the sidewall of the opening.

Example 19: the method of Example 17 or Example 18, further comprising a layer comprising titanium and/or copper between the conductive adhesive and the carrier.

Example 20: the method of Examples 17-19, wherein the carrier is removed from the substrate with a laser debonding process.

What is claimed is:

1. An apparatus, comprising:
a substrate, wherein the substrate comprises a glass layer;
an opening through a thickness of the substrate; and
a via in the opening, wherein the via directly contacts a sidewall of the opening at a first location, wherein a gap is provided between the via and the sidewall of the opening at a second location, and wherein the via is electrically conductive.

2. The apparatus of claim 1, wherein the via comprises substantially planar top and bottom surfaces, and wherein a sidewall of the via is non-linear.

3. The apparatus of claim 1, wherein the sidewall of the opening has a slope with respect to a top surface of the substrate.

4. The apparatus of claim 1, wherein a composition of the via is substantially uniform across a line from a first edge of the via to a second edge of the via, and wherein the line is parallel to a top surface and/or a bottom surface of the substrate.

5. The apparatus of claim 4, wherein the composition comprises substantially copper.

6. The apparatus of claim 1, wherein an aspect ratio (height:width) of the opening is approximately 10:1 or greater.

7. The apparatus of claim 1, wherein the gap has a width that is up to one micron.

8. The apparatus of claim 1, wherein the via has a first cross-sectional area along a plane and the opening has a second cross-sectional area along the plane, and wherein the first cross-sectional area is smaller than the second cross-sectional area.

9. The apparatus of claim 8, wherein a difference between the first cross-sectional area and the second cross-sectional area is a third cross-sectional area along the plane, and wherein the third cross-sectional area along the plane is a voided area that comprises the gap.

10. The apparatus of claim 1, wherein the substrate is a core of a package substrate.

11. An apparatus, comprising:
a substrate, wherein the substrate comprises a glass layer;
an opening through a thickness of the substrate; and
a via in the opening, wherein the via has a first cross-sectional area along a plane and the opening has a second cross-sectional area along the plane, and wherein the first cross-sectional area is smaller than the second cross-sectional area.

12. The apparatus of claim 11, wherein a sidewall of the via is non-linear.

13. The apparatus of claim 11, wherein the opening has an hourglass shaped profile.

14. The apparatus of claim 11, wherein the via comprises a composition that is substantially copper.

15. The apparatus of claim 11, wherein the substrate is a core of a package substrate.

16. The apparatus of claim 15, further comprising:
a die coupled to the package substrate; and
a board coupled to the package substrate.

17. A method, comprising:
attaching a carrier to a substrate with a conductive adhesive, wherein the conductive adhesive spans across an opening through the substrate;
plating a via in the opening with a bottom-up process from the conductive adhesive; and
removing the carrier from the substrate.

18. The method of claim 17, wherein the via directly contacts a sidewall of the opening at a first location along the sidewall of the opening, and wherein the via is spaced away from the sidewall of the opening by a gap at a second location along the sidewall of the opening.

19. The method of claim 17, further comprising a layer comprising titanium and/or copper between the conductive adhesive and the carrier.

20. The method of claim 17, wherein the carrier is removed from the substrate with a laser debonding process.
